(19) United States
(12) Patent Application Publication
(10) Pub. No.: US 2006/0236204 A1
(43) Pub. Date: Oct. 19, 2006

(54) MEMORY DEVICE WITH SERIAL TRANSMISSION INTERFACE AND ERROR CORRECTION MEHTOD FOR SERIAL TRANSMISSION INTERFACE

(76) Inventors: Yu-Chu Lee, Hsinchu County (TW); Shih-Yu Huang, Hsinchu City (TW); Han-Liang Chou, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,957

(22) Filed: Aug. 24, 2005

(30) Foreign Application Priority Data
Mar. 17, 2005 (TW) 94108147

(51) Int. Cl. G11C 29/00

(52) U.S. Cl. 714/763

(57) ABSTRACT

The present invention provides a memory device with the serial transmission interface and an error correction method for the serial transmission interface. The memory device comprises an error correction mechanism to detect or automatically correct the error earlier to make sure the correctness of the data transmission while the serial transmission interface accesses the memory. Further, the action of error corrections and data re-transmissions performed by the master device can be reduced.

### CROSS-REFERENCE TO RELATED APPLICATION

This application claims the priority benefit of Taiwan application serial no. 94108147, filed on Mar. 17, 2005. All disclosure of the Taiwan application is incorporated herein by reference.

### BACKGROUND OF THE INVENTION

1. Field of the Invention

The present invention relates to a memory device, and more particularly, to a memory device with a serial transmission interface having error correction mechanism and a method thereof.

2. Description of the Related Art

Traditionally, an access interface of a memory device, such as a flash memory, adopts a parallel transmission interface with an address bus and a data bus. Such interface needs lots of pins, and thus raises chip packaging costs. In order to reduce pin numbers, two serial transmission interfaces have been widely used. One is the serial peripheral interface (SPI), and the other is the low pin count (LPC) interface developed by Intel.

FIG. 1 is a block diagram showing a prior art SPI flash memory. Wherein, the SPI flash memory is a flash memory with the SPI. Referring to FIG. 1, the SPI flash memory 100 comprises the SPI controller 110 and the flash memory 120. The SPI controller 110 is responsible for the transformation of external data and internal data. Wherein, the external data use less data lines and the internal data use more data lines. Accordingly, the pins of the SPI flash memory 100 are reduced.

The data are transmitted between the master device 150 and the SPI flash memory 100 through the serial transmission interface. The serial transmission interface comprises the SPI controller 110 of the SPI flash memory 100 and the SPI controller 160 of the master device 150, and the SPI controllers communicate with each other by the serial clock line SCK, the enable line CEB and the external data. The SPI controller 110 of the SPI flash memory 100 is coupled to the flash memory 120 through the address data, the internal data, the enable line CE_B, the write enable line WE_B and the read enable line OE_B. The data transmission errors between the master device 150 and the SPI flash memory 100 may result from external interferences. According to the prior art technology, a checksum or an error correction mechanism is added on the master device 150 to make sure the correctness of the data transmission. Under this design, once the data transmitted to the SPI flash memory 100 is in error, the data should be re-transmitted. Furthermore, the transmission errors in the SPI flash memory 100 cannot be checked and corrected.

### SUMMARY OF THE INVENTION

Accordingly, the present invention is directed to a memory device with a serial transmission interface. An error correction mechanism is added in the memory device. Errors in the memory device can be detected or automatically corrected earlier while the serial transmission interface accesses the memory. Accordingly, error data is eliminated, and error corrections or data re-transmissions performed by the master device are reduced.

The present invention is also directed to an error correction method for a serial transmission interface. The error correction method is adapted for a memory device with a serial transmission interface. According to the error correction mechanism applied in this method, errors in the memory device can be detected or automatically corrected earlier while the serial transmission interface accesses the memory. Accordingly, error data is eliminated, and error corrections or data re-transmissions performed by the master device are reduced.

The present invention provides a memory device with a serial transmission interface, which comprises a serial transmission interface controller, a memory and an error correction code controller. The serial transmission interface controller is adapted to serially access an external data, and to send/receive an internal data in the memory device with the serial transmission interface. Wherein, the internal data comprises a digital data and a first error correction code. The memory is coupled to the serial transmission interface controller to store the digital data. The error correction code controller is coupled to the serial transmission interface controller and the memory to temporarily store the digital data outputted from the serial transmission interface controller, and to check the digital data according to the first error correction code.

According to the memory device with the serial transmission interface of a preferred embodiment of the present invention, the error correction code controller comprises a data buffer, a data recovery unit, an error correction code decoder and a register. The data buffer temporarily stores the digital data outputted from the serial transmission interface controller. The data recovery unit corrects the digital data accessed by the error correction code controller. The error correction code decoder decodes the digital data accessed by the error correction code controller to generate a second error correction code and compares the first error correction code and the second error correction code so as to determine the correctness of the digital data. When the digital data is in error, the data recovery unit is activated to correct the digital data. When the digital data is in error and the data recovery unit is unable to correct the digital data, the serial transmission interface controller re-accesses the external data. The register temporarily stores the second error correction code so that the error correction code decoder can compare the first error correction code and the second error correction code.

According to the memory device with the serial transmission interface of a preferred embodiment of the present invention, the memory comprises an error correction code block to store the first error correction code while the error correction code decoder compares the first error correction code and the second error correction code, and determines the correctness of the digital data.

According to the memory device with the serial transmission interface of a preferred embodiment of the present invention, when the memory device with the serial transmission interface read the digital data, the error correction code block provides the first error correction code stored therein; the digital data provided by the memory and the first error correction code constitute the internal data, and the internal data is transmitted to the error correction code controller to determine the correctness of the internal data.

According to the memory device with the serial transmission interface of a preferred embodiment of the present invention, the serial transmission interface controller is a serial peripheral interface (SPI) controller. The memory is a flash memory.

The present invention provides an error correction method for a serial transmission interface. The error correction method is adapted for a memory device with a serial transmission interface, comprising the following steps: in the first step, an external data is accessed and transformed to an internal data of the memory device with the serial transmission interface, wherein the internal data comprises a digital data and a first error correction code; in the second step, the digital data is checked by the memory device with the serial transmission interface according to the first error correction code.

According to the error correction method for the serial transmission interface of a preferred embodiment of the present invention, in the process of checking the digital data by the memory device with the serial transmission interface according to the first error correction code comprising the following steps: first, a second error correction code is generated according to the digital data; the first error correction code and the second error correction code then are compared to determine the correctness of the digital data; next, the digital data is corrected according to the first error correction code when the digital data is in error. However, the external data will be re-accessed by the memory device with the serial transmission interface when the digital data is found in error and the data recovery unit is unable to correct the digital data.

By adding an error correction mechanism in the memory device with the serial transmission interface, the error correction code controller checks or automatically corrects the data accessed. Accordingly, error data is eliminated, and loadings on the master device which is responsible for transmitting data to the serial transmission interface are reduced.

The above and other features of the present invention will be better understood from the following detailed description of the preferred embodiments of the invention that is provided in communication with the accompanying drawings.

### BRIEF DESCRIPTION OF THE DRAWINGS

FIG. 1 is a block diagram showing a prior art SPI flash memory.

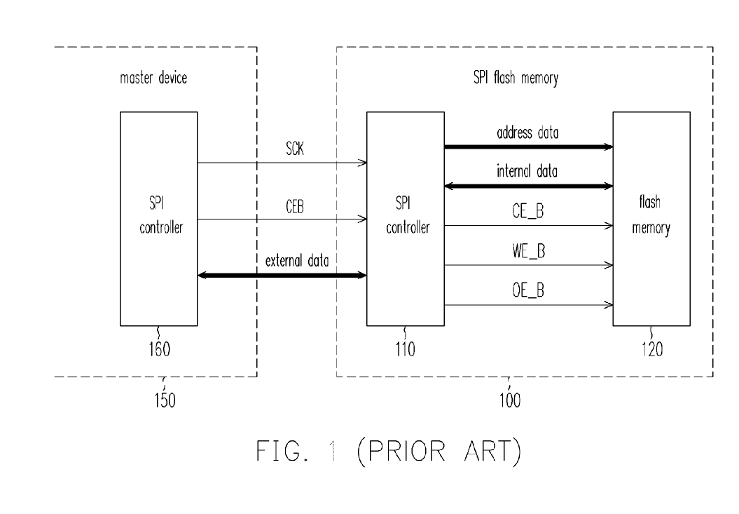

FIG. 2 is a block drawing showing an SPI flash memory according to a preferred embodiment of the present invention.

FIG. 3 is a drawing showing a signal sequence of an SPI flash memory according to a preferred embodiment of the present invention.

FIG. 4 is a flowchart showing an error correction method for a serial transmission interface according to a preferred embodiment of the present invention.

### DESCRIPTION OF SOME EMBODIMENTS

In order to clearly interpret the embodiment of the present invention, following are descriptions of an embodiment of a serial peripheral interface (SPI), and a flash memory. Accordingly, the serial transmission controller can be called as an SPI controller. The memory device with the serial transmission interface can be named as an SPI flash memory. One of ordinary skill in the art understands that it can be memory devices with other serial transmission interface. In addition, the error correction code controller is called an ECC controller, the error correction code block is called an ECC block, the error correction code encoder is called an ECC encoder, and the error correction code decoder is called an ECC decoder.

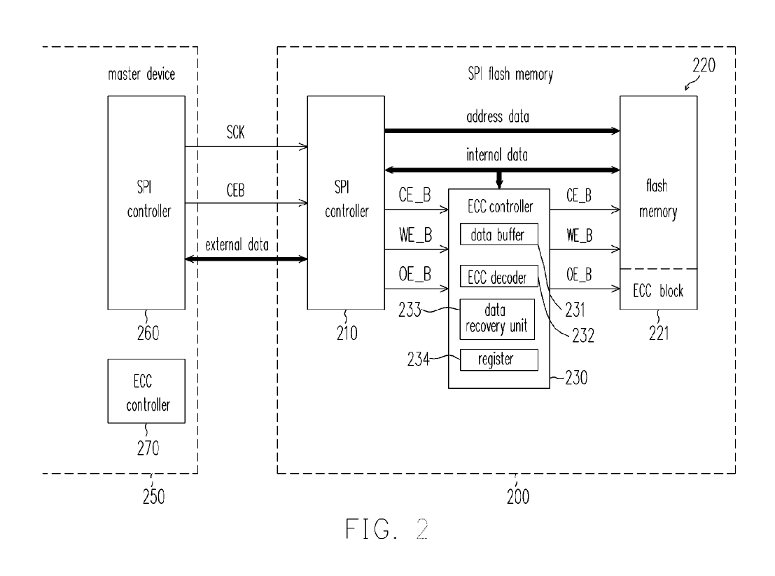

FIG. 2 is a block drawing showing an SPI flash memory according to a preferred embodiment of the present invention. Referring to FIG. 2, the SPI flash memory 200 comprises the SPI controller 210, the flash memory 220 and the ECC controller 230. The SPI controller 210 is responsible for the transformation of the external data and the internal data. Wherein, the external data use less data lines compared with the internal data. As a result, the pins of the SPI flash memory are reduced. The data are transmitted between the master device 250 and the SPI flash memory 200 through the serial transmission interface. The serial transmission interface comprises the master device 250 and the SPI controllers 210 and 260 of the SPI flash memory 200. The serial transmission interface accesses the external data through the serial clock line SCK and the enable line CEB.

In order for the errors in the SPI flash memory 200 being detected or automatically corrected earlier while accessing the SPI flash memory 200 to make sure that the data transmissions are correct, the ECC controller 230 is added in the SPI flash memory 200. Cooperating with the SPI controller 260 and the ECC controller 270 of the master device 250, the ECC controller 230 detects or automatically corrects the errors in the SPI flash memory 200 earlier.

When the master device 250 is going to write a digital data in the SPI flash memory 200, the digital data passes through the ECC encoder in the ECC controller 270 and generates a first error correction code. The first error correction code, accompanied by the digital data, is transmitted to the SPI flash memory 200 through the serial transmission interface. In other words, the digital data and the first error correction code constitute an external data, which is transmitted to the SPI controller 210 by the SPI controller 260. The external data then is transformed to an internal data which is coupled to more data lines. Of course, the internal data comprises the digital data and the first error correction code substantially similar to those of the external data.

Then, the ECC controller 230 checks the correctness of the internal data. The ECC controller 230 comprises the data buffer 231, the ECC decoder 232, the data recovery unit 233 and the register 234. The data buffer 231 temporarily stores the internal data outputted from the SPI controller 210. The ECC decoder 232 is responsible for decoding the digital data in the internal data, and generating a second error correction code which is temporarily stored in the register 234.

The ECC controller 230 compares the first and the second error correction codes to determine the correctness of the received digital data. If the digital data is correct, the internal data stored in the data buffer 231 is transmitted. According to an address data, the internal data is written in the flash memory 220. The flash memory 220 provides the ECC block 221 to store the first error correction code of the internal data. If the digital data is in error, the data recovery unit 233 is activated to correct the error which is “within a limited scope”. However, if the error is out of the correction capability of the data recovery unit 233, i.e. the error is unable to be corrected by the data recovery unit 233, the master device 250 will re-get the external data and transmit it to the SPI flash memory 200 according to the flag status of the register 234.

While accessing a digital data from the SPI flash memory 200, the master device 250 obtains the digital data from the flash memory 220 according to the address data and then obtains the first error correction code corresponding to the digital data stored in the ECC block 221. The digital data and the corresponding first error correction code constitute the internal data, which passes through the ECC controller 230. The ECC decoder 232 decodes the digital data to generate a second error correction code. The ECC controller 230 then compares the first and the second error correction codes to determine the correctness of the digital data. If the digital data is correct, the internal data stored in the data buffer 231 is transmitted. The internal data is transmitted to the master device 250 through the SPI controller 210. If the digital data is in error, the data recovery unit 233 is activated to correct the error which is “within the limited scope”. If, however, the error is unable to be corrected by the data recovery unit 233, the SPI flash memory 200 will re-read the internal data from the flash memory 220 and transmit it to the ECC controller 230 according to the flag status of the register 234.

“The limited scope” described above means the scope in which the bit numbers of the digital data that can be corrected are restricted. The bit numbers which can be corrected vary with error correction encoding/decoding structures. For example, for an error correction code with a Hamming distance≧D, the error correction code is able to detect an error with D−1 bits or below, and automatically corrects an error with (D−1)/2 bits or below, wherein D is a natural number.

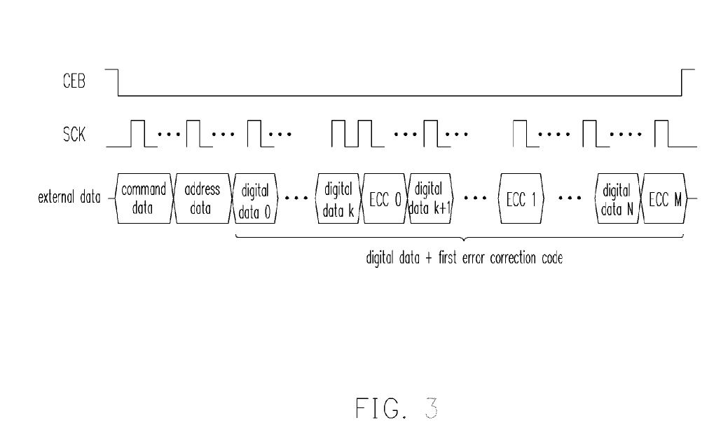

FIG. 3 is a drawing showing a signal sequence of an SPI flash memory according to a preferred embodiment of the present invention. Referring to FIGS. 2 and 3, after the master device 250 uses the enable signal CEB to enable the SPI flash memory 200, the master device 250 transmits the external data, accompanied with the serial clock signal SCK, to the SPI flash memory 200. The external data comprises command data, address data, the digital data and the first error correction code. Wherein, the master device 250 indicates the data to be read or written according to the command data, and indicates the location of the data to be written into or read from the flash memory 220 according to the address data. The digital data and the first error correction code are segmented for transmission. For example, the digital data is divided into the digital data 0−N, and the first error correction code is divided into ECC 0−M, wherein M and N are natural numbers.

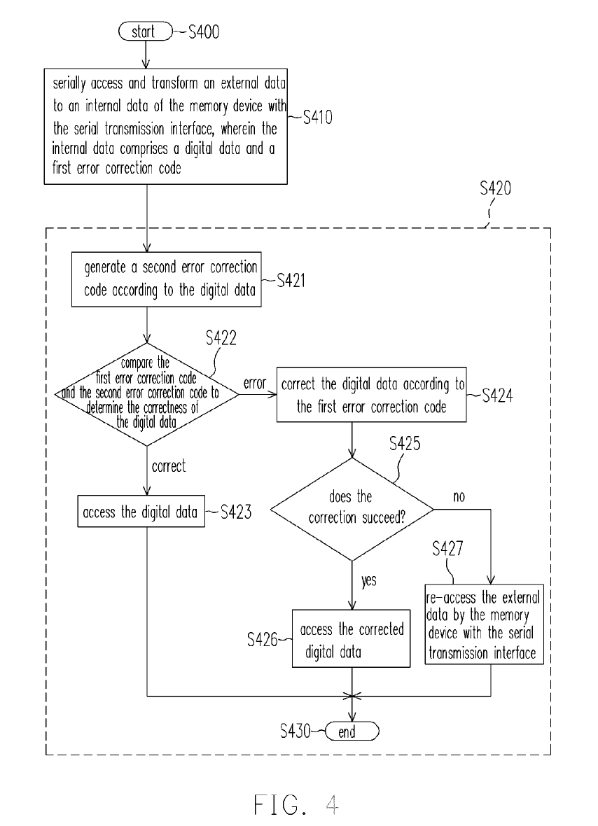

FIG. 4 is a flowchart showing an error correction method for a serial transmission interface according to a preferred embodiment of the present invention. Referring to FIG. 4, the error correction method of the present invention starts from step S400. In step S410, external data is accessed serially and transformed to internal data of the memory device with the serial transmission interface. Wherein, the internal data comprises digital data and a first error correction code. Referring to FIG. 2, the step is performed by the SPI controller 210. In step S420, the memory device with the serial transmission interface checks the digital data according to the first error correction code. Referring to FIG. 2, the step is performed by the ECC controller 230. Then, the process goes to step S430 is completed and finishes.

Step S420 further comprises the following steps: first, in step S421, a second error correction code is generated according to the digital data; next, in step S422, the first and the second error correction codes are compared to determine the correctness of the digital data; when the digital data is correct, the digital data is accessed in step S423; then the process is completed in step S430. If the digital data is in error, the digital data will be corrected according to the first error correction code in step S424. Meanwhile, step S425 will determine whether the correction is successful. If so, the corrected digital data is accessed in step S426, and the process is stopped at step S430. If the correction fails, the memory device with the serial transmission interface re-accesses the external data in step S427, and ends at step S430.

Accordingly, the present invention provides the memory device with the serial transmission interface and the error correction method for the serial transmission interface. By adding the error correction mechanism in the memory device, the errors in the memory device can be detected or automatically corrected earlier while the serial transmission interface accesses the memory. Accordingly, error data is eliminated, and loadings on the master device which is responsible for transmitting data to the serial transmission interface are reduced.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A memory device with a serial transmission interface, comprising:
a serial transmission interface controller, adapted to serially access an external data, and send/receive an internal data in the memory device with the serial transmission interface, the internal data comprising a digital data and a first error correction code;
a memory, coupled to the serial transmission interface controller to store the digital data; and
an error correction code controller, coupled to the serial transmission interface controller and the memory to temporarily store the digital data outputted from the serial transmission interface controller, and to check the digital data according to the first error correction code.

2. The memory device with a serial transmission interface of claim 1, wherein the error correction code controller comprises:
a data buffer, temporarily storing the digital data outputted from the serial transmission interface controller;
a data recovery unit, correcting the digital data accessed by the error correction code controller;
an error correction code decoder, decoding the digital data accessed by the error correction code controller to generate a second error correction code, and comparing the first error correction code and the second error correction code so as to determine the correctness of the digital data; when the digital data is in error, the data recovery unit is activated to correct the digital data; when the digital data is in error and the data recovery unit is unable to correct the digital data, the serial transmission interface controller re-accesses the external data; and
a register, temporarily storing the second error correction code so that the error correction code decoder compare the first error correction code and the second error correction code.

3. The memory device with a serial transmission interface of claim 1, wherein the memory comprises an error correction code block to store the first error correction code while the error correction code decoder compares the first error correction code and the second error correction code, and determines the correctness of the digital data.

4. The memory device with a serial transmission interface of claim 3, wherein when the memory device with the serial transmission interface read the digital data, the error correction code block provides the first error correction code stored therein; the digital data provided by the memory and the first error correction code constitute the internal data, and the internal data is transmitted to the error correction code controller to determine the correctness of the internal data.

5. The memory device with a serial transmission interface of claim 1, wherein the serial transmission interface controller is a serial peripheral interface (SPI) controller.

6. The memory device with a serial transmission interface of claim 1, wherein the memory is a flash memory.

7. An error correction method for a serial transmission interface, adapted for a memory device with a serial transmission interface, the error correction method comprising:
serially accessing and transforming an external data to an internal data of the memory device with the serial transmission interface, wherein the internal data comprises a digital data and a first error correction code; and
checking the digital data by the memory device with the serial transmission interface according to the first error correction code.

8. The error correction method for a serial transmission interface of claim 7, wherein the process of checking the digital data by the memory device with the serial transmission interface according to the first error correction code comprises the following steps:
generating a second error correction code according to the digital data;
comparing the first error correction code and the second error correction code to determine the correctness of the digital data;
correcting the digital data according to the first error correction code when the digital data is in error; and
re-accessing the external data by the memory device with the serial transmission interface when the digital data is in error and a data recovery unit is not able to correct the digital data.
